(19) United States
(12) Patent Application Publication
(10) Pub. No.: US 2012/0061809 A1
(43) Pub. Date: Mar. 15, 2012

(54) METHOD FOR MANUFACTURING SUBSTRATE FOR SEMICONDUCTOR ELEMENT, AND SEMICONDUCTOR DEVICE

(75) Inventors: Junko TODA, Kasukabe-shi (JP); Susumu Maniwa, Kasukabe-shi (JP); Yasuhiro Sakai, Tamana-shi (JP); Takehito Tsukamoto, Tokorozawa-shi (JP)

(73) Assignee: TOPPAN PRINTING CO., LTD, Tokyo (JP)

(21) Appl. No.: 13/234,630

(22) Filed: Sep. 16, 2011

Related U.S. Application Data
(63) Continuation of application No. PCT/JP2010/001829, filed on Mar. 15, 2010.

(30) Foreign Application Priority Data
Mar. 17, 2009 (JP) P2009-064231

(51) Int. Cl. H01L 23/495; C23F 1/02

(52) U.S. Cl. 257/666; 216/14; 257/E23.049

(57) ABSTRACT

Provided is a manufacturing method of a substrate for a semiconductor element, the manufacturing method including the steps of: providing a first photosensitive resin layer at a first surface of a metal plate; providing a second photosensitive resin layer at a second surface of the metal plate different from the first surface; forming a first etching mask for forming a connection post on the first surface of the metal plate; forming a second etching mask for forming a wiring post on the second surface of the metal plate; forming the connection post by performing an etching on the first surface of the metal plate from a first surface side to a midway of the metal plate; applying a premold resin in liquid form to the first surface of the metal plate which underwent the etching on the first surface; forming a premold resin layer by solidifying the premold resin in liquid form being applied; and forming a wiring pattern by performing an etching on the second surface of the metal plate from a second surface side.

### CROSS REFERENCE TO RELATED APPLICATIONS

This application is a continuation application based on a PCT Patent Application No. PCT/JP2010/001829, filed Mar. 15, 2010, whose priority is claimed on Japanese Patent Application No. 2009-064231, filed Mar. 17, 2009, the entire content of which is hereby incorporated by reference.

### BACKGROUND OF THE INVENTION

1. Field of the Invention

The present invention relates to a substrate for a semiconductor element. The semiconductor element is mounted on the substrate. In particular, the present invention relates to a method for manufacturing a substrate which is shaped as a lead frame. The present invention also relates to a semiconductor device using the substrate shaped as a lead frame.

2. Description of the Related Art

Various types of semiconductor elements such as memory, CMOS, CPU, and the like, are manufactured by a wafer process. These semiconductor elements have a terminal for electrical connection. The magnitude of the pitch of the terminal for electrical connection is different from the magnitude of the pitch of the connection part at a print substrate side by approximately several to several hundred times. A semiconductor element is attached to the connection part at the print substrate side. Therefore, when the semiconductor element is about to be connected with the print substrate, an intermediary substrate (a substrate for mounting a semiconductor element) called an “interposer” is used for pitch conversion.

The semiconductor element is mounted on one side of this interposer. A connection with the print substrate is made at another surface or a peripheral of the substrate. The interposer includes a metallic lead frame in the interior or at a front surface. An electrical connection channel is routed by the lead frame. In this way, the pitch of an external connection terminal is expanded. The external connection terminal makes a connection with the print substrate.

FIGS. 2A-2C are schematic diagrams showing a structure of an interposer using a QFN (Quad Flat Non-lead) type lead frame, which is an example of a conventional interposer.

As shown in FIG. 2A, a flat part 15 of a lead frame is provided at a central part of a lead frame. The lead frame is formed primarily of either aluminum or copper. A semiconductor element 16 is mounted on the flat part 15 of the lead frame. A lead 17 with a wide pitch is placed at an outer peripheral part of the lead frame. A wire bonding method is used to connect the lead 17 and the terminal for electrical connection of the semiconductor element 16. The wire bonding method uses a metal wire 18 such as an Au line and the like. As shown in FIG. 2B, an overall integration is made at a final stage by performing a molding process with a molding resin 19.

Incidentally, a holding material 21 shown in FIGS. 2A and 2B is used to hold a lead frame. The holding material 21 is removed as shown in FIG. 2C, after a molding is performed with the molding resin 19.

However, according to the interposer shown in FIGS. 2A-2C, an electrical connection can be made only at an outer peripheral part of the semiconductor element 16 and an outer peripheral part of the lead frame. Therefore, there was a problem in that the interposer is not suitable for a semiconductor element having a large number of terminals.

When the semiconductor element has a small number of terminals, the connection between the print substrate and the interposer is conducted by attaching a metallic pin on an extraction electrode 20 at an outer peripheral part of the interposer. Furthermore, when the semiconductor element has a large number of terminals, a BGA (Ball Grid Array) is used. According to the BGA, a solder ball is positioned in an array pattern at an external connection terminal at an outer peripheral part of the interposer.

According to a semiconductor element having a small area and a large number of terminals, it is difficult to convert a pitch when an interposer has only one layer of wiring layer. Therefore, a procedure is often conducted to increase the number of wiring layer included in the interposer, thereby stacking a plurality of wiring layers.

A connection terminal of a semiconductor element, having a small area and a large number of terminals, is often formed at a bottom surface of the semiconductor element by being placed in an array form. Therefore, a flip chip connection method is often used. According to this flip chip connection method, an external connection terminal at an interposer side is placed in an array form which is the same as a connection terminal of a semiconductor element. Furthermore, according to this flip chip connection method, a minimal amount of solder ball is used to connect the interposer and the print substrate. The wiring inside the interposer is created by forming a hole from an upper part in a perpendicular direction with a drill or a laser and the like, forming a metallic plating inside the hole, and thereby creating electrical conductivity between the upper and lower layers. According to an interposer configured according to this method, the pitch of the external connection terminal may be made small to approximately 150 to 200 μm. As a result, it is possible to increase the number of connection terminals.

However, the reliability and stability of the connection are reduced. Thus, the above configuration is not suitable for mounting on a vehicle, which requires a high degree of reliability.

Several types of interposers have been designed. The material used to create the interposer and the structure of the interposer are different. For example, an interposer is configured so that ceramic is used in the structure of a portion holding the lead frame part. Another type of interposer is configured so that the base material of the interposer is an organic substance such as P-BGA (Plastic Ball Grid Array), CSP (Chip Size Package), or LGA (Land Grid Array). These interposers are utilized as appropriate according to actual use and required configurations.

As the size of semiconductor elements become smaller, as the number of pins increases, and/or as the speed of the semiconductor elements increases, adjustments are made by the interposers described above. For example, a fine pitching and an adjustment to high speed signals are made. Fine pitching refers to a decrease in the size of the pitch of the connection part connecting with the semiconductor element. Taking into consideration that the pitch has become more and more minute, it is necessary that the pitch of a terminal portion of recent interposers be approximately 80 to 100 μm.

Incidentally, the lead frame is used as a conduction part and a supporting component. As a representative example, the lead frame is formed by applying an etching process on a thin metallic plate. It is preferable that the thickness of the metal plate be equal to approximately 120 μm, so that the etching process may be performed with stability, and so that an appropriate handling is made in the procedures after the etching process. Furthermore, a certain level of thickness and a land area is required for the metallic layer to contribute to an adequate amount of joint strength during the wire bonding process.

Taking these conditions into consideration, it is necessary that the thickness of the metallic plate for the lead frame be at least approximately 100 to 120 μm.

Furthermore, in this case, when an etching processing is performed from both sides of the metallic plate, it is believed that the pitch of the lead may be minimized to approximately 120 μm, while the width of the lead line may be minimized to approximately 60 μm.

Another problem is that, during a process of manufacturing an interposer, it is necessary to discard the holding material, as shown in FIG. 2C. This discarding procedure is regarded as a waste in terms of material costs and processing costs. Therefore, the discarding procedure is believed to lead to an increase in costs. An explanation in this regard is provided below using FIGS. 2A-2C.

The lead frame is attached to the holding material 21 made of polyimid tape. A semiconductor element 16 is fixed to a flat part 15 of the lead frame with a fixing resin or a fixing tape 22.

Thereafter, a wire bonding is performed. According to the transfer mold method, a plurality of chips, i.e., the semiconductor element 16, are integrally molded by the molding resin 19.

Thereafter, an external processing is performed. A cutting is made so that each interposer becomes independent.

When a back surface of the lead frame becomes a connection surface connecting with a print substrate, it is necessary to prevent the molding resin 19 from wrapping around a connection terminal surface of a back surface of the lead frame and sticking to the connection terminal during molding. Therefore, the holding material 21 has been necessary in a process manufacturing an interposer.

However, in the end, the holding material 21 is unnecessary. Thus, after a molding procedure is performed, it is necessary to remove the holding material 21 and discard it. This leads to an increase in costs.

Japanese Unexamined Patent Application, First Publication No. H10-223828 shows an example of a substrate for a semiconductor element shaped as a lead frame. The substrate for a semiconductor element is structured so that a premold resin layer is a supporting body of a wiring. In this way, Japanese Unexamined Patent Application, First Publication No. H10-223828 shows an example of a method providing a substrate for a semiconductor element which solves the problems described above, allows the formation of a wiring with an extremely small pitch (i.e., a wiring with an ultrafine pitch), enables a wire bonding processing in a stable manner, and is cost-effective.

Hereinafter, a method, disclosed in Japanese Unexamined Patent Application, First Publication No. H10-223828, of manufacturing a substrate for a semiconductor element in the form of a lead frame is described.

For example, a resist pattern for forming a connection post is created on a first surface of a copper metallic plate. A resist pattern for forming a wiring pattern is created on a second surface of the copper metallic plate. An etching procedure is conducted on the metallic plate from above the first surface to a desired thickness. Thereafter, a premold resin is applied to the first surface, thereby forming a premold layer. Then, an etching procedure is conducted from the second surface, a wiring is formed, and finally, the resist on both sides are peeled off.

According to the substrate for a semiconductor element in the form of a lead frame, manufactured as described above, when the thickness of the metal is made as thin as possible to a level at which a fine etching process is possible, an etching procedure can be performed in a stable manner because the premold resin is acting as a supporting body. Furthermore, since the scattering of an ultrasonic wave energy is small, the wire bonding characteristics are superior as well. In addition, since a holding material such as a polyimid tape is not used, it is possible to reduce the cost used for the holding material.

However, there is a problem in the technology described in Patent Document 1. According to the technology described in Patent Document 1, a potting method is used to apply a premold resin in a liquid state to a surface of a metallic plate which has been etched halfway in a thickness direction. However, this is technically difficult. The thickness of the film that is applied must be thick enough to provide the necessary rigidity to the lead frame. At the same time, the bottom surface of the connection post must be completely exposed.

A concrete solution for applying a resin while controlling the thickness is, for example, a method in which a syringe and the like is used to pour resin into one point of a bottom of an applied surface, and wait until the resin permeates the entire applied surface. However, the premold resin has a certain degree of viscosity. As a result, it may require too much time for the premold resin to permeate the entire applied surface. This is problematic in terms of productivity.

In addition, the premold resin may become spherical due to the effects of surface tension. As a result, the premold resin might cluster in a narrow region. In this case, even if the amount of premold resin that was infused is small, the height might become large, thereby causing a faulty condition. A different faulty condition might occur due to the resin being applied to a height higher than the height of the connection post.

In addition, a solution may be devised by using an equipment such as a dispenser and the like, and by providing a plurality of infusion points at the bottom of the applied surface. However, the viscosity of the premold resin is high. As a result, various faulty conditions might occur. For example, while the premold resin moves from a certain infusion point to another location, string might be formed from this premold resin, and the string might stick to the bottom surface of the connection post. As another example, since the premold resin moves along the applied surface, bubbles might be formed in the premold resin.

The present invention is made according to the problems described above. Thus, the present invention provides a semiconductor device and a method for manufacturing a substrate for a semiconductor element, which allows a premold resin to be easily applied for an appropriate thickness during a process of manufacturing a substrate for a semiconductor element shaped like a lead frame provided with a premold using resin in a liquid form.

### SUMMARY

A manufacturing method of a substrate for a semiconductor element according to an aspect of the present invention includes a masking step; a molding step; and a wiring pattern formation step. The masking step includes the steps of providing a first photosensitive resin layer at a first surface of a metal plate; providing a second photosensitive resin layer at a second surface of the metal plate different from the first surface; forming a first etching mask for forming a connection post on the first surface of the metal plate by selectively performing an exposure to the first photosensitive resin layer according to a first pattern, and by developing the first photosensitive resin layer, the first etching mask including the first photosensitive resin layer which was developed; and forming a second etching mask for forming a wiring post on the second surface of the metal plate by selectively performing an exposure to the second photosensitive resin layer according to a second pattern, and by developing the second photosensitive resin layer, the second etching mask including the second photosensitive resin layer which was developed. The molding step includes the steps of: after the masking step, forming the connection post by performing an etching on the first surface of the metal plate from a first surface side to a midway of the metal plate; applying a premold resin in liquid form to the first surface of the metal plate which underwent the etching on the first surface; and forming a premold resin layer by solidifying the premold resin in liquid form being applied. The wiring pattern formation step includes a step of forming a wiring pattern by performing an etching on the second surface of the metal plate from a second surface side.

The manufacturing method of a substrate for a semiconductor element may be configured as follows: the premold resin in liquid form is applied in a vacuum chamber.

The manufacturing method of a substrate for a semiconductor element may be configured as follows: the premold resin in liquid form is applied up to a thickness not higher than a height of the connection post.

The manufacturing method of a substrate for a semiconductor element may be configured as follows: the first etching mask and the second etching mask are peeled off after the molding step and the wiring pattern formation step are completed.

The manufacturing method of a substrate for a semiconductor element may be configured as follows: the first etching mask and the second etching mask are peeled off after the molding step and the wiring pattern formation step are completed.

A substrate for a semiconductor element according to an aspect of the present invention includes a metal plate including a first surface and a second surface different from the first surface; a connection post placed at the first surface of the metal plate; a wiring pattern placed at the second surface of the metal plate; and a premold resin layer wherein a premold resin is filled in a portion at which the connection post of the first surface does not exist.

A substrate for a semiconductor according to an aspect of the present invention is configured so that a semiconductor element is mounted on the substrate for a semiconductor element described above; and the semiconductor element and the substrate for a semiconductor element are electrically connected by a wire bonding.

The substrate for a semiconductor element may be configured as follows: a height of the premold resin layer is not higher than a height of the connection post.

The substrate for a semiconductor may be configured as follows: a height of the premold resin layer is not higher than a height of the connection post.

According to the present invention, when a substrate shaped like a lead frame provided with a premold is manufactured, it is possible to prevent the height of the premold resin in liquid form from being higher than the height of the connection post, without bubbles being included in the resin and in an easy manner.

This height of the premold resin is advantageous in that there is an adequate amount of rigidity as a supporting body of the substrate shaped like a lead frame, and that the connection post can be easily exposed. Therefore, a high degree of reliability and a high degree of joint strength may be obtained in addition to having an adequate amount of mechanical strength and forming an electrical connection.

### BRIEF DESCRIPTION OF THE DRAWINGS

FIG. 1A is a descriptive view schematically showing a process for manufacturing a substrate for a semiconductor element shaped like a lead frame according to an embodiment of the present invention.

FIG. 1B is a descriptive view schematically showing a process for manufacturing a substrate for a semiconductor element shaped like a lead frame according to an embodiment of the present invention.

FIG. 1C is a descriptive view schematically showing a process for manufacturing a substrate for a semiconductor element shaped like a lead frame according to an embodiment of the present invention.

FIG. 1D is a descriptive view schematically showing a process for manufacturing a substrate for a semiconductor element shaped like a lead frame according to an embodiment of the present invention.

FIG. 1E is a descriptive view schematically showing a process for manufacturing a substrate for a semiconductor element shaped like a lead frame according to an embodiment of the present invention.

FIG. 1F is a descriptive view schematically showing a process for manufacturing a substrate for a semiconductor element shaped like a lead frame according to an embodiment of the present invention.

FIG. 1G is a descriptive view schematically showing a process for manufacturing a substrate for a semiconductor element shaped like a lead frame according to an embodiment of the present invention.

FIG. 1H is a descriptive view schematically showing a process for manufacturing a substrate for a semiconductor element shaped like a lead frame according to an embodiment of the present invention.

FIG. 2A is a diagram schematically showing a structure of an interposer using a QFN (Quad Flat Non-lead) type lead frame, which is an example of a conventional interposer.

FIG. 2B is a diagram schematically showing a structure of an interposer using a QFN (Quad Flat Non-lead) type lead frame, which is an example of a conventional interposer.

FIG. 2C is a diagram schematically showing a structure of an interposer using a QFN (Quad Flat Non-lead) type lead frame, which is an example of a conventional interposer.

### DETAILED DESCRIPTION OF THE PREFERRED EMBODIMENTS

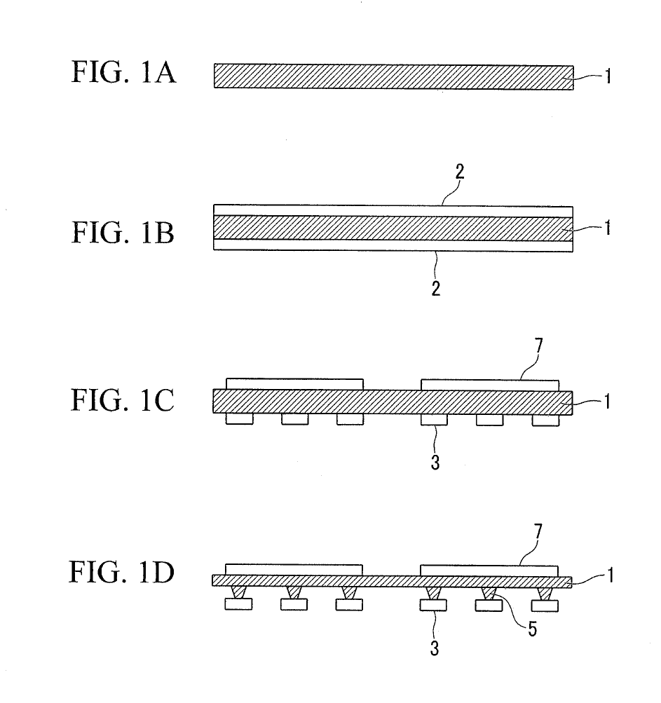

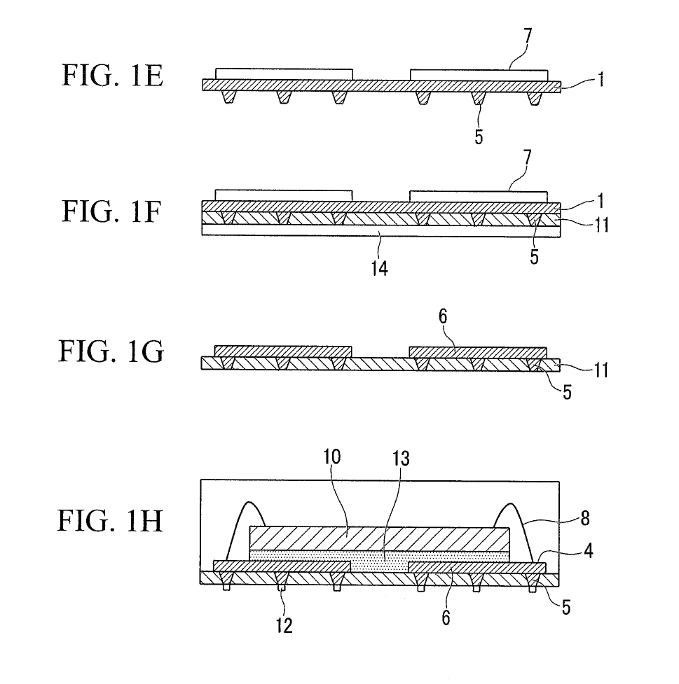

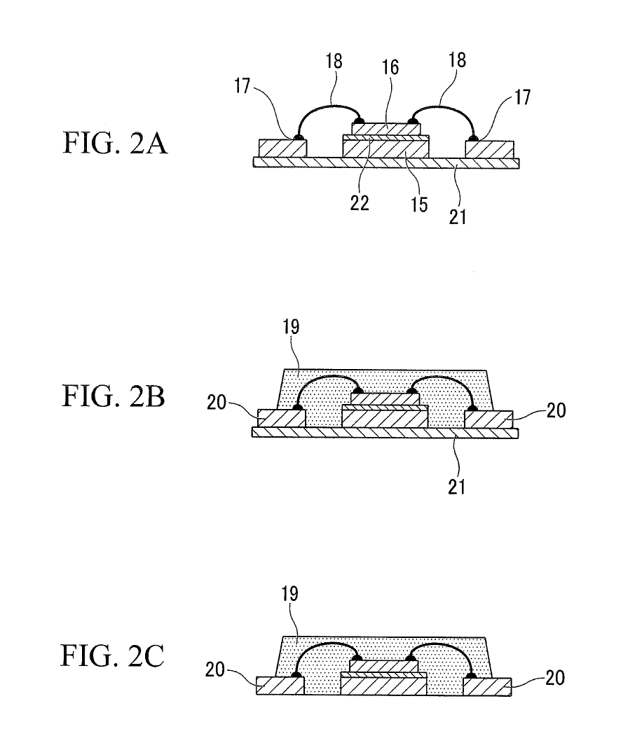

Hereinafter, an embodiment of a method for manufacturing a substrate shaped like a lead frame according to an aspect of the present invention is described with reference to FIGS. 1A-1H, with an LGA type substrate for a semiconductor element being given as an example.

### Working Example

The size of each individual unit of the manufactured LGA is 10 mm angle. The LGA has an external connection part. The external connection part is shaped like an array from a planar view with 168 pins. This LGA is mounted on the substrate at multiple surfaces. After the following manufacturing steps are performed, a cutting is made, a trimming is made, and individual substrates of an LGA type are obtained. These substrates are shaped like a lead frame.

First, as shown in FIG. 1A, a long, band-like copper substrate 1 is provided. The width of the substrate is 150 mm, while the thickness of the substrate is 150 μm. Next, as shown in FIG. 1B, a photosensitive resist 2 (OFPR4000, manufactured by Tokyo Ohka Kogyo, Co., Ltd.) is coated to both surfaces of the copper substrate 1 with a roll coater. The photosensitive resist 2 is coated so that the thickness of the photosensitive resist 2 is 5 μm. Thereafter, a prebaking is performed at a temperature of 90° C.

Next, a pattern exposure is performed from both surfaces via a pattern exposure photo mask. The pattern exposure photo mask has a desired pattern. Thereafter, a processing procedure is conducted using a 1% sodium hydroxide solution. Thereafter, a cleansing is made with water, and a post baking is conducted. In this way, as shown in FIG. 1C, a first resist pattern 3 and a second resist pattern 7 were obtained.

Incidentally, a first resist pattern 3 is formed on one surface side (i.e., a surface which is opposite to a surface on which a semiconductor element 10 is mounted; hereinafter, the “one surface side” is referred to as a first surface side in the present embodiment) of the copper substrate 1 in order to form a connection post 5. A second resist pattern 7 is formed on another surface side (i.e., a surface on which a semiconductor element 10 is mounted; hereinafter, the “another surface side” is referred to as a second surface side in the present embodiment) of the copper substrate 1 in order to create a wiring pattern.

Incidentally, as shown in FIG. 1H, the semiconductor element 10 is mounted on an upper surface of the lead frame at a central part of the copper substrate 1. According to the wiring pattern based on the present embodiment, a land 4 for a wire bonding is formed on the upper surface of the outer peripheral of the lead frame near the outer peripheral of the semiconductor element 10. The outer peripheral of the semiconductor element 10 and the land 4 are connected with a metallic fine line 8. A connection post 5 is placed at a back surface of the lead frame in, for example, an array form seen from a planar view. The connection post 5 is used to guide an electronic signal from an upper part wiring to a back side.

In addition, it is necessary to electrically connect some of the lands 4 to the connection post 5. A wiring pattern 6 is connected to each of the several lands 4. Therefore, a connection is made in a radial fashion, for example, from an outer peripheral of the substrate towards a central direction (not diagrammed), so that the wiring pattern 6 is connected with the connection post 5.

Next, after the second surface side of the copper substrate is protected by covering the second surface side with a back sheet, a ferric chloride solution is used to perform a first etching procedure from the first surface side of the copper substrate. As shown in FIG. 1D, the thickness of a portion of the copper substrate 1 which is exposed from the first resist pattern 3 at the first surface side is made thinner to 30 μm.

The specific weight of the ferric chloride solution is 1.38. The temperature of the ferric chloride solution is 50° C. During the first etching, an etching procedure is not performed on a portion of the copper substrate 1, at which the first resist pattern 3 is created for forming the connection post 5. In this way, the connection post 5 is formed. The connection post 5 can establish an external connection with the print substrate. The connection post 5 extends in the width direction of the copper substrate 1. The height of the connection post 5 is equal to a distance from an etching surface, formed by the first etching process, to a lower side surface of the copper substrate 1.

Incidentally, during the first etching process, only a partial etching is performed. In other words, the first etching process does not completely dissolve and remove the portion of the copper substrate 1 at which an etching is performed. The first etching is finished when a predetermined thickness of the copper substrate 1 is reached.

Next, as shown in FIG. 1E, the resist pattern 3 was peeled off using a 20% aqueous sodium hydroxide with respect to the first surface. The temperature of the peeling liquid is 100° C.

Next as shown in FIG. 1F, a potting method was used to apply a premolding resin in liquid form to a lower surface of the first surface formed by the first etching process. A thermohardening resin in liquid form (“SMC-376KF1” manufactured by Shin-Etsu Chemical Co., Ltd.) is used as the premolding resin in liquid form. A demolding film 14 is placed over the applied premolding resin in liquid form. The demolding film 14 has a low elasticity coefficient of 5-0.01 GPa. The premold resin layer 11 was formed by performing a pressing operation inside a vacuum chamber. The thickness of the demolding film 14 is adjusted so that the premolding resin in liquid form was filled up to a height such that the premolding resin in liquid form does not cover the bottom surface of the connection post. In this way, the thickness of the demolding film 14 was set to be 130 μm.

A vacuum pressurized laminated device was used for the pressing operation. The temperature of the pressing part was set to be 100° C. The degree of vacuum inside the vacuum chamber was set to be 0.2 torr. The pressing time was 30 seconds. Under this condition, the pressing operation of the premold resin in liquid form was conducted.

Performing a vacuum pressing operation while covering the premolding resin in liquid form with a demolding film 14 having a low elasticity coefficient is effective in many aspects. First, for example, a procedure based on the potting method using a resin in liquid form becomes easier. Second, since the amount of the premolding resin in liquid form being applied is adjusted, it is possible to prevent the resin from covering the connection post 5. Third, since the connection post may be made higher than the resin surface, it is possible to establish a stable connection with the print substrate.

Furthermore, by performing a pressing operation inside a vacuum chamber, an air gap formed inside the resin can be eliminated, thereby preventing the occurrence of a void inside the resin.

In addition, after the pressing operation was conducted on the resin in liquid form, a post baking process was performed by heating at a temperature of 180° C. for sixty minutes. The demolding film was removed after the premold resin underwent a post baking process. Then, after the back sheet of the second surface was removed, an etching was performed on the second surface. A ferric chloride solution was used as the etching liquid. The specific weight of the etching liquid was 1.32. The temperature of the etching liquid was 50° C. A goal of the etching process is to form a wiring pattern 6 on the second surface. Copper, which was exposed from the second resist pattern 7 over the second surface, was dissolved and removed. Next, as shown in FIG. 1G the second resist pattern 7 on the second surface, and the demolding film 14, were peeled off. In this way, a desired LGA shaped like a lead frame was obtained.

Next, a plated layer 12 was formed by conducting a surface processing on the metallic surface of the exposed first surface. The surface processing was conducted using a non-electrolytic nickel/palladium/gold plating forming method.

Here, the plated layer 12 of the lead frame may be formed by using an electrolytic plating method. However, when an electrolytic plating method is used, it is necessary to form a plating electrode in order to supply a plating current. Thus, since the plating electrode is formed, the wired region becomes smaller. Hence, there is a concern that the wiring may become difficult.

From this aspect, it is generally more preferable to use the non-electrolytic nickel/palladium/gold plating forming method, which does not require an electrode for supplying a plating current.

According to the present working example, the plating layer 12 was formed by conducting on the metallic surface, an acid delipidation, a soft etching, acid cleansing, a platinum catalyzer activation procedure, a pre-dipping, a non-electrolytic platinum plating, and a non-electrolytic gold plating.

The thickness of the nickel plating is 3 μm, the thickness of the palladium plating is 0.2 μm, and the thickness of the gold plating is 0.03 μm.

Enplate NI (manufactured by Meltex Inc.) was used as the plating liquid for nickel plating. Paulobond EP (manufactured by Rohm and Haas) was used as the plating liquid for palladium plating. Paulobond IG (manufactured by Rohm and Haas) was used as the plating liquid for gold plating.

Next, the semiconductor element 10 was bonded and mounted on top of a lead frame using a bonding adhesive or a bonding tape 13. Thereafter, a wire bonding was performed on an electrical connection terminal of the semiconductor element 10 and a land for a wire bonding of a wiring pattern. This wire bonding was performed using a metallic fine line 8. Then, a molding was performed so as to cover the lead frame and the semiconductor element 10. Thereafter, a cutting operation was performed on the semiconductor substrate which was attached to a surface. In this way, individual semiconductor substrates were obtained.

According to a method for manufacturing a substrate for a semiconductor element and a semiconductor device based on the present working example, a premolding resin with an appropriate thickness can be easily provided in a process for manufacturing a substrate for a semiconductor element shaped like a lead frame and having a premold using a resin in liquid form.

A favorable working example according to the present invention has been described above. However, the description provided above only presents an example of the present invention. The technical scope of the present invention is not limited by the embodiments described above. Various alterations may be made without deviating from the gist of the present invention. In other words, the present invention is not to be limited to the working example presented above, and is limited by the attached claims.

According to the present invention, when a substrate shaped like a lead frame and having a premold is manufactured, it is possible to make the height of the premold resin in liquid form to be equal to or lower than the height of the connection post in a easy manner without including any air bubbles.

This height of the premold resin is advantageous in that the premold resin has an adequate level of rigidity as a supporting body of the substrate shaped like a lead frame, and that the connection post can be easily exposed. Therefore, it is possible to obtain a high degree of reliability and a high degree of joint strength with respect to attaining an adequate degree of mechanical strength and performing an electrical connection.

1. A manufacturing method of a substrate for a semiconductor element, the manufacturing method comprising:
masking;
molding; and
wiring pattern forming, wherein
the masking comprises
providing a first photosensitive resin layer at a first surface of a metal plate,
providing a second photosensitive resin layer at a second surface of the metal plate different from the first surface,
forming a first etching mask for forming a connection post on the first surface of the metal plate by selectively performing an exposure to the first photosensitive resin layer according to a first pattern, and by developing the first photosensitive resin layer, the first etching mask comprising the first photosensitive resin layer which was developed, and
forming a second etching mask for forming a wiring post on the second surface of the metal plate by selectively performing an exposure to the second photosensitive resin layer according to a second pattern, and by developing the second photosensitive resin layer, the second etching mask comprising the second photosensitive resin layer which was developed;
the molding comprises
after the masking, forming the connection post by performing an etching on the first surface of the metal plate from a first surface side to a midway of the metal plate,
applying a premold resin in liquid form to the first surface of the metal plate which underwent the etching on the first surface, and
forming a premold resin layer by solidifying the premold resin in liquid form being applied; and
the wiring pattern forming comprises
forming a wiring pattern by performing an etching on the second surface of the metal plate from a second surface side.

2. The manufacturing method of a substrate for a semiconductor element according to claim 1, wherein the premold resin in liquid form is applied in a vacuum chamber.

3. The manufacturing method of a substrate for a semiconductor element according to claim 1, wherein the premold resin in liquid form is applied up to a thickness not higher than a height of the connection post.

4. The manufacturing method of a substrate for a semiconductor element according to claim 1, wherein the first etching mask and the second etching mask are peeled off after the molding and the wiring pattern forming are completed.

5. The manufacturing method of a substrate for a semiconductor element according to claim 3, wherein the first etching mask and the second etching mask are peeled off after the molding and the wiring pattern forming are completed.

6. A substrate for a semiconductor element, the substrate comprising:
a metal plate comprising a first surface and a second surface different from the first surface;
a connection post placed at the first surface of the metal plate;
a wiring pattern placed at the second surface of the metal plate; and
a premold resin layer wherein a premold resin is filled in a portion at which the connection post of the first surface does not exist.

7. A substrate for a semiconductor wherein:
a semiconductor element is mounted on the substrate for a semiconductor element according to claim 6; and
the semiconductor element and the substrate for a semiconductor element are electrically connected by a wire bonding.

8. The substrate for a semiconductor element according to claim 6, wherein a height of the premold resin layer is not higher than a height of the connection post.

9. The substrate for a semiconductor according to claim 7, wherein a height of the premold resin layer is not higher than a height of the connection post.

10. The manufacturing method of a substrate for a semiconductor element according to claim 2, wherein the premold resin in liquid form is applied up to a thickness not higher than a height of the connection post.

11. The manufacturing method of a substrate for a semiconductor element according to claim 2, wherein the first etching mask and the second etching mask are peeled off after the molding and the wiring pattern forming are completed.

12. The manufacturing method of a substrate for a semiconductor element according to claim 10, wherein the first etching mask and the second etching mask are peeled off after the molding and the wiring pattern forming are completed.
